(19) United States
(12) Patent Application Publication
(10) Pub. No.: US 2025/0309006 A1
(43) Pub. Date: Oct. 2, 2025

(54) SEMICONDUCTOR TEST STRUCTURE AND METHOD FOR MANUFACTURING THE SAME

(71) Applicant: NANYA TECHNOLOGY CORPORATION, New Taipei city (TW)

(72) Inventors: Ming Hsun WU, New Taipei City (TW); Hsueh-Han LU, New Taipei City (TW); Yao Ching CHIU, New Taipei City (TW)

(21) Appl. No.: 18/619,273

(22) Filed: Mar. 28, 2024

(51) Int. Cl. H01L 21/66

(52) U.S. Cl. CPC H01L 22/32; H01L 22/14

(57) ABSTRACT

A semiconductor test structure includes a substrate, an input, an output, contacts, top electrodes, and connecting lines. The substrate includes a testing area which including some isolation areas and some active areas spaced apart by the isolation areas, in which each active area has a major axis and has a first end and a second end thereon. The input and the output are disposed at opposite sides of the testing area, in which the first ends face toward the input and the second ends face toward the output. The contacts are disposed on the active areas. The top electrodes are disposed on the contacts. The connecting lines disposed between the active areas. Adjacent two top electrodes are electrically connected by one connecting line. The active areas, the contacts, the top electrodes, and the connecting lines form a testing path that is substantially straight.

### BACKGROUND

### Field of Invention

The present disclosure relates to a semiconductor test structure and a method for manufacturing the semiconductor test structure.

### Description of Related Art

The dynamic random access memory (DRAM) is a semiconductor memory that randomly writes and reads data at high speed, and is widely used in data storage devices. It is typically composed of multiple memory cells, each of which includes a transistor and a capacitor. The gate of the transistor is electrically connected to a word line (WL) of the DRAM, and on and off of the transistor is controlled by the voltage on the WL. One terminal of the transistor is electrically connected to a bit line (BL) through a bit line contact (BLC), and the other terminal of the transistor is electrically connected to the capacitor, such that data is stored or output through the BL. The resistance of the BLC is a major factor affecting the timeliness of data transfer. Therefore, it is necessary to measure the resistance of the BLC through a test structure.

However, the test structure of resistance measurement in the related art needs at least two masks to form top electrodes and connecting lines, which may increase the process time and cause imprecise alignment.

### SUMMARY

In accordance with an aspect of the present disclosure a semiconductor test structure is provided. The semiconductor test structure includes a substrate, an input and an output, a plurality of contacts, a plurality of top electrodes, and a plurality of connecting lines. The substrate includes a testing area, and the testing area includes an isolation area and a plurality of active areas spaced apart by the isolation area, in which each active area has a major axis and has a first end and a second end thereon. The input and the output are disposed at opposite sides of the testing area, in which the first ends face toward the input and the second ends face toward the output. The contacts are disposed on the active areas, in which each contact corresponds to the first end or the second end of each active area. The top electrodes are disposed on the contacts, in which each top electrode corresponds to one of the contacts. The connecting lines are disposed between the active areas. Adjacent two top electrodes are electrically connected by one connecting line. The active areas, the contacts, the top electrodes, and the connecting lines form a testing path that is substantially straight.

According to some embodiments of the present disclosure, each contact is in direct contact with the first ends or the second ends.

According to some embodiments of the present disclosure, each top electrode is in direct contact with one of the contacts corresponding.

According to some embodiments of the present disclosure, the input is connected to one of the top electrodes on the testing path closest to the input.

According to some embodiments of the present disclosure, the output is connected to one of the top electrodes on the testing path closest to the output.

According to some embodiments of the present disclosure, the top electrodes, the connecting lines, the input, and the output are at a same level.

According to some embodiments of the present disclosure, a configuration between the contacts and the top electrodes is one to one.

According to some embodiments of the present disclosure, the testing path is substantially parallel to the major axes of the active areas.

In accordance with another aspect of the present disclosure, a method for manufacturing a semiconductor test structure is provided and includes the following steps. Defining a testing area in a substrate and forming a plurality of active areas and an isolation area in the testing area, in which the active areas are spaced apart by the isolation area, and each active area has a major axis and has a first end and a second end. Forming a plurality of contacts on the active areas, in which each contact corresponds to the first end or the second end of each active area. Forming a plurality of top electrodes on the contacts, in which each top electrode corresponds to one of the contacts. Forming an input and an output at opposite sides of the testing area, in which the first ends face toward the input and the second ends face toward the output. Forming a plurality of connecting lines between the active areas, in which adjacent two top electrodes are electrically connected by one connecting line. The active areas, the contacts, the top electrodes, and the connecting lines form a testing path that is substantially straight.

According to some embodiments of the present disclosure, forming the top electrodes, forming the connecting lines, forming the input and the output are performed at a same process step.

According to some embodiments of the present disclosure, forming the top electrodes, forming the connecting lines, and forming the input and the output are performed by an extreme ultraviolet lithography process.

According to some embodiments of the present disclosure, each top electrode is substantially aligned with one of the contacts.

According to some embodiments of the present disclosure, the connecting lines are electrically connected to the input and the output.

According to some embodiments of the present disclosure, the contacts are in direct contact with the first end or the second end of each active area.

According to some embodiments of the present disclosure, the top electrodes, the connecting lines, the input and the output are at a same level.

According to some embodiments of the present disclosure, the testing path is substantially parallel to the major axis of each active area.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a top view of a semiconductor test structure in accordance with various embodiments of the present disclosure.

FIG. 2 is a cross-sectional view of a semiconductor test structure in accordance with various embodiments of the present disclosure.

FIG. 3 is a top view of a semiconductor test structure in accordance with a comparative example of the present disclosure.

FIG. 4 is a top view of a semiconductor test structure in accordance with a comparative example of the present disclosure.

FIG. 5 is a top view of a semiconductor test structure in accordance with a comparative example of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

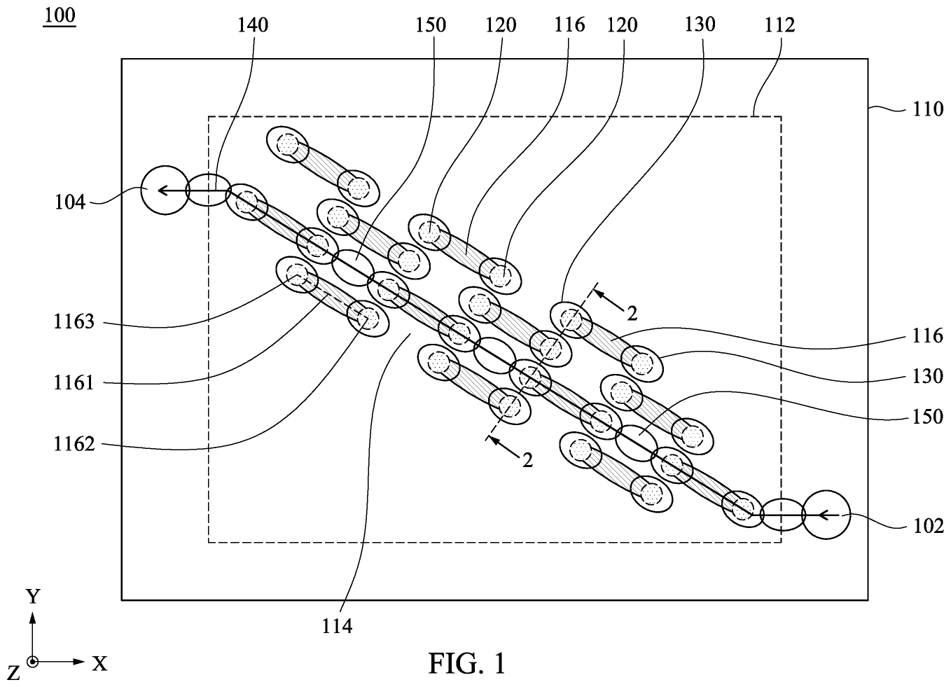

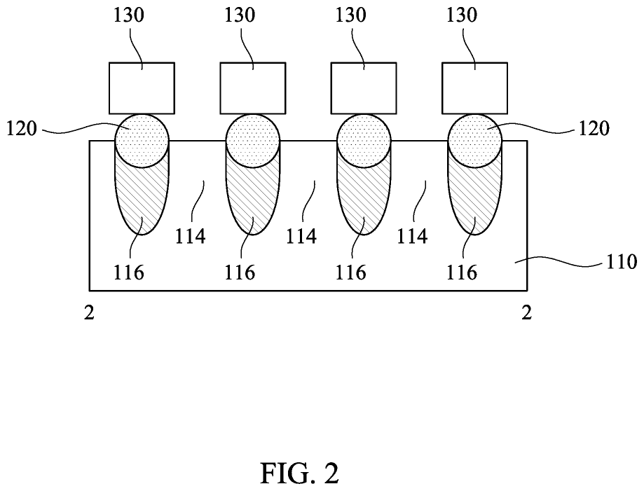

FIG. 1 is a top view of a semiconductor test structure 100 in accordance with various embodiments of the present disclosure. FIG. 2 is a cross sectional view along line 2-2 of FIG. 1. Reference is made to FIG. 1. The semiconductor test structure 100 includes a substrate 110, an input 102, an output 104, a plurality of contacts 120, a plurality of top electrodes 130, and a plurality of connecting lines 150. To be specific, the substrate 110 includes a testing area 112 as shown in FIG. 1. Please refer to FIG. 1 and FIG. 2 at the same time, the testing area 112 includes the isolation area 114 and a plurality of active areas 116 spaced apart by the isolation area 114.

The substrate 110 may include, for example, silicon (e.g., crystalline silicon, polycrystalline silicon, or amorphous silicon). In some embodiments, the substrate 110 may include other elementary semiconductor such as germanium. In some embodiments, the substrate 110 may include an alloy semiconductor such as silicon germanium, silicon germanium carbide, gallium indium phosphide and the like. In some embodiments, the substrate 110 may include compound semiconductor such as gallium arsenic (GaAs), silicon carbide (SiC), indium phosphide (InP), indium arsenide (InAs) and the like. Further, the substrate 110 may optionally include a semiconductor-on-insulator (SOI) structure. In some embodiments, the substrate 110 further includes doped regions such as a P-well and/or an N-well (not shown). In some other embodiments, the substrate 110 further includes other features such as a buried layer. In other embodiments, the substrate 110 includes a gradient semiconductor layer, and/or further includes a semiconductor layer overlying another semiconductor layer of a different type such as a silicon layer on a silicon germanium layer.

The isolation area 114 may be formed through a shallow trench isolation (STI) process. The isolation area 114 may include, for example, a material including at least one of silicon oxide, silicon nitride, and silicon oxynitride. The isolation area 114 may be a single layer including one kind of insulator, a double layer including two kinds of insulators, or a multilayer including a combination of at least three kinds of insulators. For example, the isolation area 114 may include silicon oxide and silicon nitride. For example, the isolation area 114 may include a triple layer including silicon oxide, silicon nitride, and silicon oxynitride.

In some embodiments, the isolation area 114 can be formed by the following steps. A pad oxide layer (not shown) is formed over the substrate 110. Next, a pad nitride layer (not shown) is formed. The pad oxide layer reduces stress on the substrate 110 from the pad nitride layer. Next, a patterned photoresist layer (not shown) defining a location of the isolation area 114 is formed on the pad nitride layer. A portion of the pad nitride layer, a portion of the pad oxide layer and a portion of the substrate 110 exposed through the patterned photoresist layer are then removed, and a shallow trench (not shown) is formed in the substrate 110. After removal of the patterned photoresist layer, sidewalls and a bottom of the shallow trench are lined by an oxide liner (not shown) and the shallow trench is filled with an insulating material such as oxide. For example, a high density plasma chemical vapor deposition oxide (HDP oxide) may be used to fill the shallow trench, but the disclosure is not limited thereto. In some embodiments, an ion implantation may be selectively performed to implant boron (B) into the substrate 110 exposed through the shallow trench before filling the shallow trench with the insulating material for further improving electrical isolation, but the disclosure is not limited thereto. Subsequently, a planarization process is performed to remove superfluous oxide with the pad nitride layer serving as a stop layer. Next, the well region can be formed in the substrate 110 and the pad nitride layer and the pad oxide layer can subsequently be removed.

Referring to FIG. 1, each active area 116 has a major axis 1161 and has a first end 1162 and a second end 1163. In some embodiment, the major axis 1161 of each active area 116 may extend in a diagonal axis with respect to an X axis. In some embodiments, each active area 116 includes an island shape surrounded by the isolation area 114 in a plan view, as shown in FIG. 1. Accordingly, the active areas 116 may be arranged along rows and columns to form an array.

Still referring to FIG. 1, the input 102 and the output 104 are disposed at opposite sides of the testing area 112. To be specific, the first ends 1162 of the active areas 116 face toward the input 102, while the second ends 1163 of the active areas 116 face toward the output 104.

Referring to FIG. 1 and FIG. 2 at the same time, the contacts 120 are disposed on the active areas 116. To be specific, each contact 120 corresponds to the first end 1162 or the second end 1163 of each active area 116. In other words, each contact 120 is substantially aligned with the first end 1162 or the second end 1163 of each active area 116. The term “substantially aligned” used herein refers to a vertical projection of each contact 120 overlapped with a vertical projection of each first end 1162 or each second end 1163 of each active area 116. According to some embodiments of the present disclosure, one active area 116 may be electrically connected to two contacts 120 disposed on the first end 1162 and the second end 1163, respectively. According to some embodiments of the present disclosure, each first end 1162 has one of the contacts 120 thereon, and the contacts 120 are in direct contact with the first ends 1162. Similarly, each second end 1163 has one of the contacts 120 thereon, and the contacts 120 are in direct contact with the second ends 1163.

Still referring to FIG. 1 and FIG. 2 at the same time, the top electrodes 130 are disposed on the contacts 120. To be specific, each top electrode 130 corresponds to one of the contacts 120. According to some embodiments of the present disclosure, each contact 120 has corresponding one of the top electrodes 130 thereon, and the top electrodes 130 are in direct contact with the contacts 120. It may be understood that a configuration between the contacts 120 and the top electrodes 130 is one to one. In some embodiments, the top electrodes 130 may include metal nitride or metal such as tungsten, tungsten nitride, and/or titanium nitride.

Referring to FIG. 1, the connecting lines 150 are disposed between the active areas 116. To be specific, adjacent two top electrodes 130 are electrically connected by one connecting line 150. The active areas 116, the contacts 120, the top electrodes 130, and the connecting lines 150 form a testing path 140. It is noted that the testing path 140 is substantially straight. According to some embodiments of the present disclosure, the testing path 140 is substantially parallel to the major axes 1161 of the active areas 116. According to some embodiments of the present disclosure, the top electrodes 130, the connecting lines 150, the input 102, and the output 104 are at a same level. In some embodiments, materials included in the connecting lines 150 are substantially identical to materials included in the top electrodes 130, and therefore no further descriptions are elaborated therein.

According to some embodiments of the present disclosure, the input 102 is connected to one of the top electrodes 130 on the testing path 140 closest to the input 102. Similarly, the output 104 is connected to one of the top electrodes 130 on the testing path 140 closest to the output 104. In some embodiments, materials included in the input 102 and the output 104 are substantially identical to materials included in the top electrodes 130, and therefore no further descriptions are elaborated therein.

In accordance with another aspect of the present disclosure, a method for manufacturing the semiconductor test structure 100 above is provided and includes the following operations. Various operations and/or steps of embodiments are provided herein. The order in which some or all of the operations and/or steps are described should not be construed to imply that these operations and/or steps are necessarily order dependent. Alternative ordering will be appreciated having the benefit of this description. Further, it will be understood that not all operations and/or steps are necessarily present in each embodiment provided herein. Also, it will be understood that not all operations and/or steps are necessary in some embodiments.

Referring to FIG. 1 and FIG. 2 at the same time, a testing area 112 is defined in the substrate 110, and a plurality of active areas 116 and an isolation areas 114 are formed in the testing area 112. To be specific, the active areas 116 are spaced apart by the isolation area 114. Each active area 116 has a major axis 1161 and has a first end 1162 and a second end 1163, as shown in FIG. 1. More specifically, the major axis 1161 of each active area 116 may extend in a diagonal axis with respect to an X axis. According to some embodiments of the present disclosure, the isolation area 114 may be formed through a shallow trench isolation (STI) process as mentioned previously.

Still referring to FIG. 1 and FIG. 2 at the same time, a plurality of contacts 120 are formed on the active areas 116. More specifically, each contact 120 corresponds to the first end 1162 or the second end 1163 of each active area 116. According to some embodiments of the present disclosure, an insulation layer (not shown) may be formed first over the substrate 110 to cover the active areas 116 and isolation areas 114. The insulation layer is used to isolate it from other subsequently formed components. For example, the insulation layer (not shown) may be made of any suitable dielectric material, such as silicon oxide, boro-phospho silicate glass (BPSG), or traethylorthosilicate (TEOS), but the present disclosure is not limited to the above material. Then, a plurality of openings (not shown) may expose a portion of active areas 116 of the substrate 110 so as to define contacts 120. The openings (not shown) are then filled with a conductive material to form the contacts 120. The contacts 120 directly contacts the portion of the active areas 116 of the substrate 110, leading to an electrical connection between the contacts 120 and the active areas 116. For example, the conductive material may include aluminum, tungsten, copper, cobalt or other suitable metals or metal alloys. In some embodiments, the contacts 120 are in direct contact with the first end 1162 or the second end 1163 of each active area 116.

Still referring to FIG. 1 and FIG. 2 at the same time, a plurality of top electrodes 130 are formed on the contacts 120. To be specific, each top electrode 130 corresponds to one of the contacts 120. According to some embodiments of the present disclosure, the shapes of the top electrodes 130 (e.g., the size, location, profiles of their lateral protrusions, and the like) may be defined with sufficient precision performing by an extreme ultraviolet (EUV) lithography process. In greater details, the extreme ultraviolet lithography process includes deposing a reflective optics device with multilayer mirrors surrounding a hydrogen gas, and injecting the tin (Sn) plasma from a light source. The hydrogen gas is used to prevent the deposition of tin which would otherwise deposit on a surface of the mirrors of the reflective optics device. In some embodiments, the extreme ultraviolet lithography process is utilized to an extreme ultraviolet wavelength (e.g., 13.5 nm) to form the top electrodes 130. The extreme ultraviolet lithography process is beneficial to form the shape (e.g., oval shape, rectangle shape, circle shape, square shape, and the like) of the top electrodes 130. In some embodiments, each top electrode 130 is substantially aligned with the corresponding contact 120. In some embodiments, the top electrodes 130 may include metal nitride or metal such as tungsten, tungsten nitride, and/or titanium nitride.

Referring to FIG. 1, an input 102 and an output 104 are formed at opposite sides of the testing area 112. To be specific, the first ends 1162 of the active areas 116 face toward the input 102 and the second ends 1163 of the active areas 116 face toward the output 104. According to some embodiments of the present disclosure, the input 102 and the output 104 may be performed by an extreme ultraviolet (EUV) lithography process. In some embodiments, materials included in the input 102 and the output 104 are substantially identical to materials included in the top electrodes 130, and therefore no further descriptions are elaborated therein.

Still referring to FIG. 1, a plurality of connecting lines 150 are formed between the active areas 116. Specifically, adjacent two top electrodes 130 are electrically connected by one connecting line 150. The active areas 116, the contacts 120, the top electrodes 130, and the connecting lines 105 form a testing path 140. It should be noted that the testing path 140 is substantially straight. In some embodiment, the testing path 140 is substantially parallel to the major axis 1161 of each active area 116. According to some embodiments of the present disclosure, the connecting lines 150 may be performed by an extreme ultraviolet (EUV) lithography process. In some embodiments, materials included in the connecting lines 150 are substantially identical to materials included in the top electrodes 130, and therefore no further descriptions are elaborated therein. As shown in FIG. 1, the connecting lines 150 are electrically connected the input 102 and the output 104.

It should be noted that the top electrodes 130, the connecting lines 150, the input 102 and the output 104 are performed at a same process step. It should be noted that the top electrodes 130, the connecting lines 150, the input 102 and the output 104 are at a same level. It may be understood that because EUV light has a very small wavelength, EUV light can be utilized to define very small features on the semiconductor structure. Therefore, the testing path 140 (including the top electrodes 130, the connecting lines 150, the input 102 and the output 104) may be formed at a same process step with one mask.

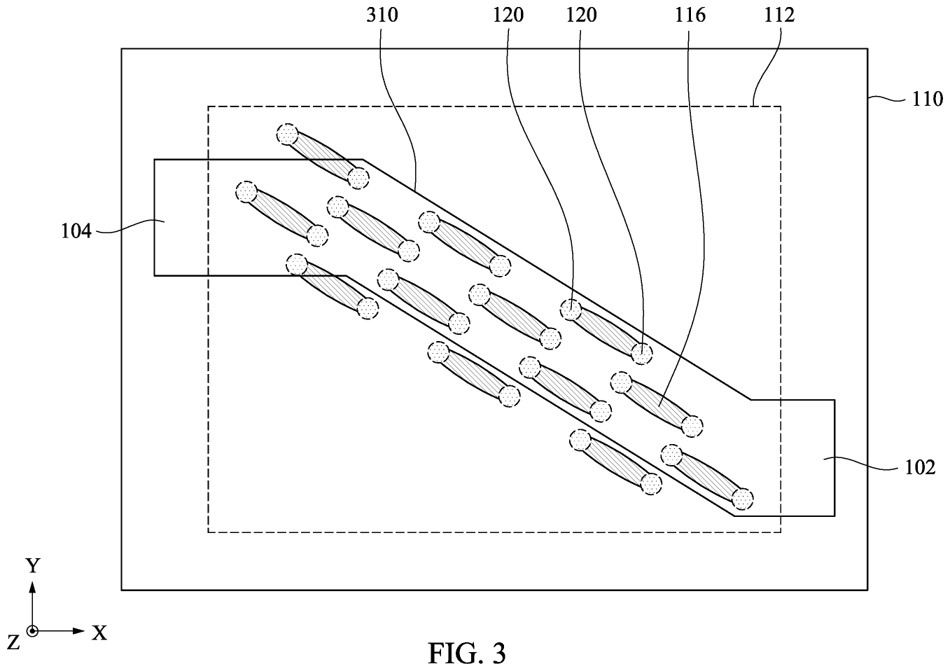

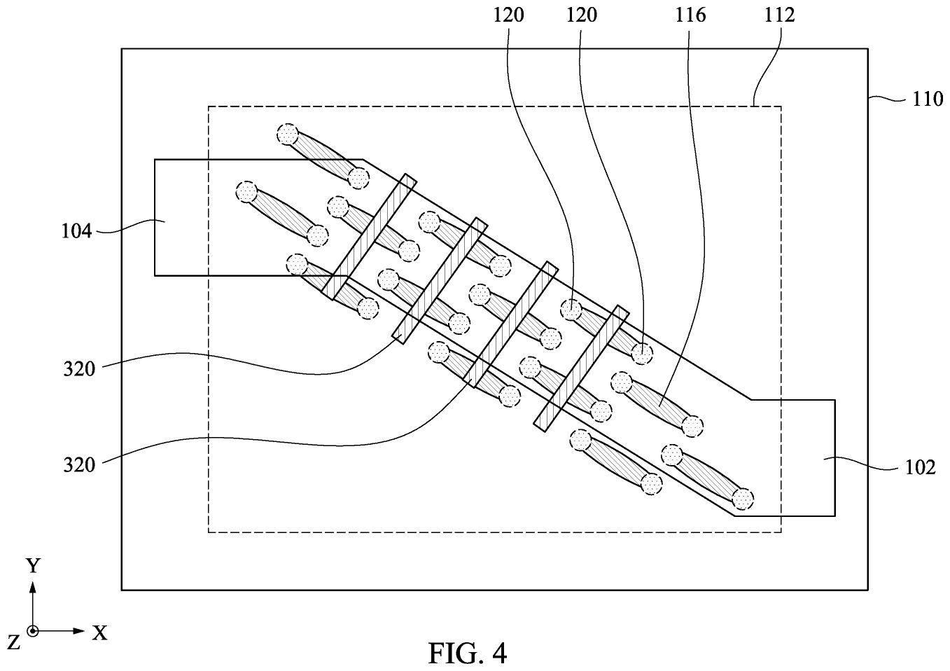

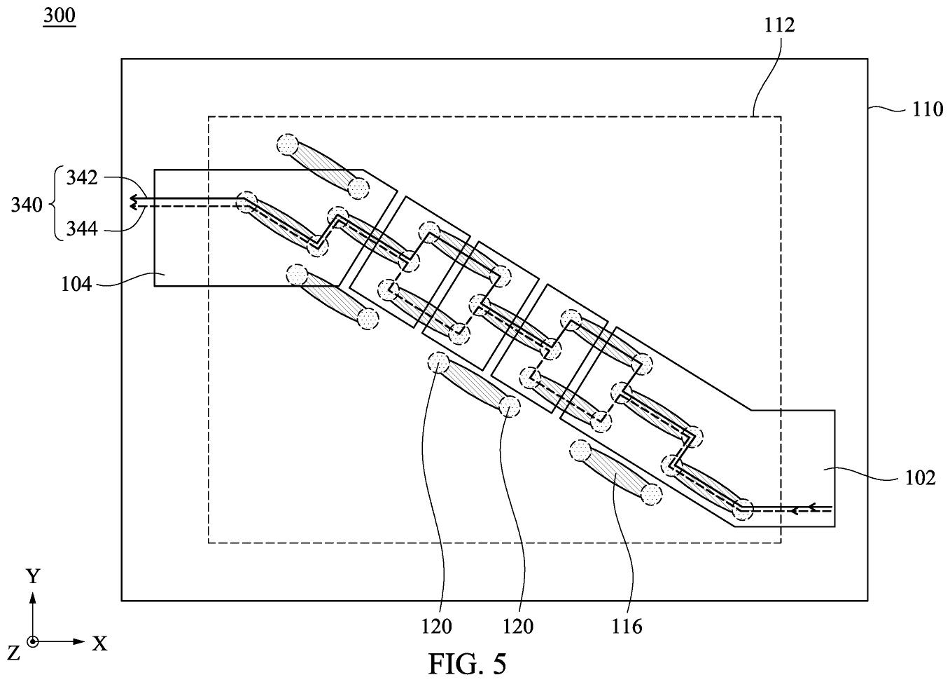

FIGS. 3-5 are top views of a semiconductor test structure 300 in accordance with a comparative example of the present disclosure, in which FIGS. 3-4 are top views of various stages of fabricating the semiconductor test structure 300.

Referring to FIGS. 3-5 at the same time, a testing path 340 is formed with at least two masks 310 and 320 in the comparative example. The lithography process (e.g. UV lithography) produces patterns with lower resolution compared to EUV lithography, so the patterns have a larger area. The first mask 310 is first used to define the desired test path range. It should be understood that the pattern defined by the first mask 310 is equivalent to the pattern of the conductive layer (including the top electrode, the connecting line, the input and the output) after transfer. The second masks 320 are then used to cut off the whole conductive layer so that the current may flow to the active area 116 below through the contact 120. Although expected test path 340 may be formed, the test path 340 may include two or more current path 342 and 344. Therefore, the test path 340 obtained by this method can only roughly calculate the resistance of the contact 120. In addition, the test path 340 obtained by this method is not a straight line.

The above embodiments provide various advantages. With the above-mentioned method and configuration thereof, only one expected test path may be formed by using the EUV process. In addition, the top electrodes and the metal pattern layer (including the connecting lines and the input and the output) may be formed at a same process step with one mask. As such, the manufacturing time may be greatly reduced and the accuracy of the test path may be improved, thereby measuring the actual resistance value of the contacts.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor test structure, comprising:
a substrate comprising a testing area, the testing area comprising an isolation area and a plurality of active areas spaced apart by the isolation area, wherein each active area has a major axis and has a first end and a second end;
an input and an output disposed at opposite sides of the testing area, wherein the first ends face toward the input and the second ends face toward the output;
a plurality of contacts disposed on the active areas, wherein each contact corresponds to the first end or the second end of each active area;
a plurality of top electrodes disposed on the contacts, wherein each top electrode corresponds to one of the contacts; and
a plurality of connecting lines disposed between the active areas, wherein adjacent two top electrodes are electrically connected by one connecting line, and the active areas, the contacts, the top electrodes, and the connecting lines form a testing path that is substantially straight.

2. The semiconductor test structure of claim 1, wherein each contact is in direct contact with the first ends or the second ends.

3. The semiconductor test structure of claim 1, wherein each top electrode is in direct contact with one of the contacts corresponding.

4. The semiconductor test structure of claim 1, wherein the input is connected to one of the top electrodes on the testing path closest to the input.

5. The semiconductor test structure of claim 1, wherein the output is connected to one of the top electrodes on the testing path closest to the output.

6. The semiconductor test structure of claim 1, wherein the top electrodes, the connecting lines, the input, and the output are at a same level.

7. The semiconductor test structure of claim 1, wherein a configuration between the contacts and the top electrodes is one to one.

8. The semiconductor test structure of claim 1, wherein the testing path is substantially parallel to the major axes of the active areas.

9. A method for manufacturing a semiconductor test structure, comprising:
defining a testing area in a substrate;
forming a plurality of active areas and an isolation area in the testing area, wherein the active areas are spaced apart by the isolation area, and each active area has a major axis and has a first end and a second end;
forming a plurality of contacts on the active areas, wherein each contact corresponds to the first end or the second end of each active area;
forming a plurality of top electrodes on the contacts, wherein each top electrode corresponds to one of the contacts;
forming an input and an output at opposite sides of the testing area, wherein the first ends face toward the input and the second ends face toward the output; and
forming a plurality of connecting lines between the active areas, wherein adjacent two top electrodes are electrically connected by one connecting line, and the active areas, the contacts, the top electrodes, and the connecting lines form a testing path that is substantially straight.

10. The method of claim 9, wherein forming the top electrodes, wherein forming the connecting lines, forming the input and the output are performed at a same process step.

11. The method of claim 9, forming the top electrodes, wherein forming the connecting lines, and forming the input and the output are performed by an extreme ultraviolet lithography process.

12. The method of claim 9, wherein each top electrode is substantially aligned with one of the contacts.

13. The method of claim 9, wherein the connecting lines are electrically connected to the input and the output.

14. The method of claim 9, wherein the contacts are in direct contact with the first end or the second end of each active area.

15. The method of claim 9, wherein the top electrodes, the connecting lines, the input and the output are at a same level.

16. The method of claim 9, wherein the testing path is substantially parallel to the major axis of each active area.
